(19) United States
(12) Patent Application Publication
(10) Pub. No.: US 2016/0164459 A1
(43) Pub. Date: Jun. 9, 2016

(54) OSCILLATOR AND SEMICONDUCTOR DEVICE INCLUDING THE SAME

(71) Applicant: SK hynix Inc., Gyeonggi-do (KR)

(72) Inventor: Dong-Wook KIM, Gyeonggi-do (KR)

(21) Appl. No.: 14/705,715

(22) Filed: May 6, 2015

(30) Foreign Application Priority Data
Dec. 5, 2014 (KR) 10-2014-0174018

(51) Int. Cl. H03B 5/04; H03K 3/03; H03B 5/24

(52) U.S. Cl. CPC H03B 5/04; H03B 5/24; H03K 3/0322

(57) ABSTRACT

An oscillator may include first to N-th delay signal generation units, each of which delays and inverts an input signal thereof. Each of the first to N-th delay signal generation units includes an inverter suitable for driving a first node with a low level voltage when a voltage of an input node thereof is higher than a first reference voltage, and driving the first node with a high level voltage when the voltage of the input node thereof is lower than the first reference in voltage; a RC delay unit electrically coupled between the first node and a second node, and suitable for to delaying a signal of the first node and outputting the delayed signal of the first node to the second node; and a buffer suitable for outputting a high level signal when a voltage of the second node is higher than a second reference voltage, and outputting a low level signal when the voltage of the second node is lower than the second reference voltage.

### CROSS-REFERENCE TO RELATED APPLICATIONS

The present application claims priority of Korean Patent Application No. 10-2014-0174018, filed on Dec. 5, 2014, which is incorporated herein by reference in its entirety.

### BACKGROUND

1. Field

Exemplary embodiments of the present invention relate to an oscillator and a semiconductor device.

2. Description of the Related Art

Periodic signals are used for operations in internal circuits of devices such memory devices, integrated circuit (IC) chips, micro controllers, etc. Periodic signals are generated by an oscillator.

It is very important for periodic signals to have a precise period. When the period of the periodic signal varies due to PVT (process, voltage and temperature) conditions, etc., devices that operate in synchronization with the periodic signal may become unreliable or even fail, Thus, various design methods for oscillators to generate precise periodic signals have been developed.

### SUMMARY

Various embodiments are directed to an oscillator for generating a periodic signal, a period of which is robust to factors other than an RC delay.

According to an exemplary embodiment of the present invention, an oscillator may include first to N-th delay signal generation units (N is an odd number), each of which delays and inverts an input signal thereof. Each of the first to N-th delay signal generation units may include: an inverter suitable for driving a first node with a low level voltage when a voltage of an input node thereof is higher than a first reference voltage, and driving the first node with a high level voltage when the voltage of the input node thereof is lower than the first reference voltage; a RC delay unit electrically coupled between the first node and a second node, and suitable for delaying a signal of the first node and outputting the delayed signal of the first node to the second node; and a buffer suitable for outputting a high level signal when a voltage of the second node is higher than a second reference voltage, and output a low level signal when the voltage of the second node is lower than the second reference voltage.

According to an exemplary embodiment of the present invention, an oscillator may include first to N-th delay units (N is an odd number), each of which delays and inverts an input signal thereof; and first to N-th buffers, each of which outputs a high level signal when a level of an input signal thereof is higher than a first reference voltage and outputs a low level signal when the level of the input signal thereof is lower than the first reference voltage. The first to N-th delay units and the first to N-th buffers may be alternately and electrically coupled in series. The N-th buffer may be electrically coupled between the N-th delay unit and the first delay unit.

According to an exemplary embodiment of the present invention, a semiconductor device may include a periodic signal generation unit suitable for generating a periodic signal; and an internal circuit suitable for operating in synchronization with the periodic signal. The periodic signal generation unit may include: first to N-th delay units (N is an odd number), each of which delays and inverts an input signal thereof; and first to N-th buffers, each of which outputs a high level signal when a level of an input signal thereof is higher than a first reference voltage and outputs a low level signal when the level of the input signal thereof is lower than the first reference voltage. The first to N-th delay units and the first to N-th buffers may be alternately and electrically coupled in series. The N-th buffer may be electrically coupled between the N-th delay unit and the first delay unit.

### BRIEF DESCRIPTION OF THE DRAWINGS

FIG. 1 is a circuit diagram illustrating a conventional oscillator.

FIG. 2 is a schematic diagram illustrating an operation of a conventional oscillator shown in FIG. 1.

FIG. 3 is a circuit diagram illustrating an oscillator according to an exemplary embodiment of the present invention.

FIG. 4 is a schematic diagram illustrating an operation of an oscillator shown in FIG. 3.

FIG. 5 is a table illustrating operational parameters of oscillators shown in FIGS. 1 and 3.

FIG. 6 is a circuit diagram illustrating an oscillator according to an exemplary embodiment of the present invention.

FIG. 7 is a circuit diagram illustrating an oscillator according to an exemplary embodiment of the present invention.

FIG. 8 is a circuit diagram illustrating an oscillator according to an exemplary embodiment of the present invention.

FIG. 9 is a block diagram illustrating a semiconductor device according to an exemplary embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

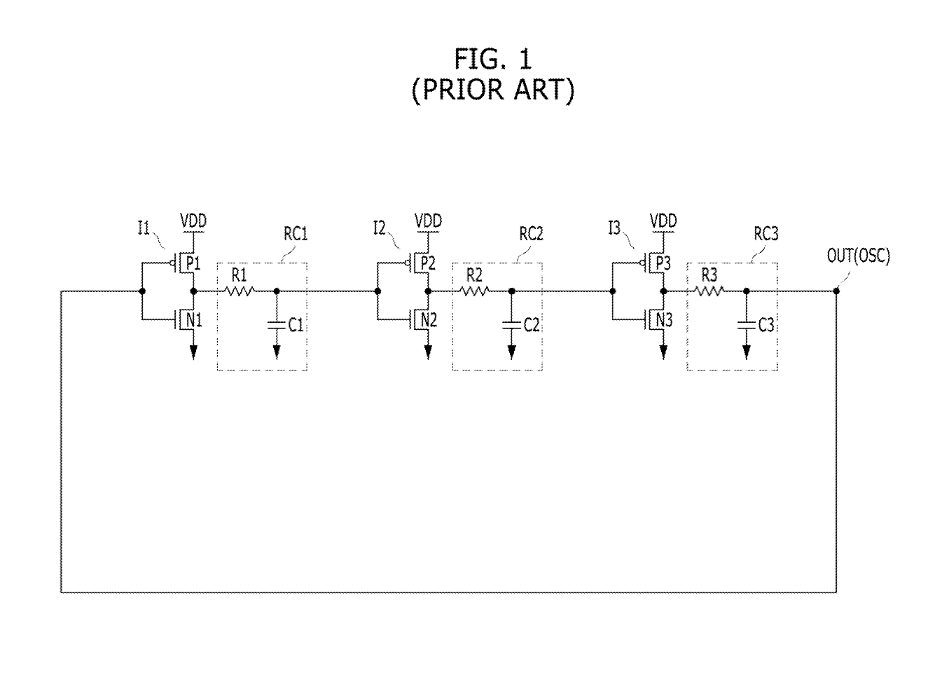

FIG. 1 is a circuit diagram illustrating a conventional oscillator.

Referring to FIG. 1, the oscillator includes an odd number of inverters I1 to I3 and an odd number of RC delay units RC1 to RC3, The oscillator outputs a periodic signal OSC through an output node OUT. The RC delay units RC1 to RC3 include capacitors C1 to C3 and resistors R1 to R3, respectively. The inverters I1 to I3 include N-MOS transistors N1 to N3 and P-MOS transistors P1 to P3, respectively.

Referring to FIG. 1, each one of the inverters I1 to I3 inverts an input signal thereof, each one of the RC delay units RC1 to RC3 delays an input signal thereof by a RC delay value, and thus, the last one of the RC delay units RC1 to RC3 outputs the periodic signal OSC through the output node OUT. The RC delay value of the RC delay units is adjusted to determine a period of the periodic signal OSC. In this case, the period of the periodic signal OSC is affected by a resistance value of the inverters I1 to I3 as well as the RC delay value and, thus, the period cannot be precisely adjusted.

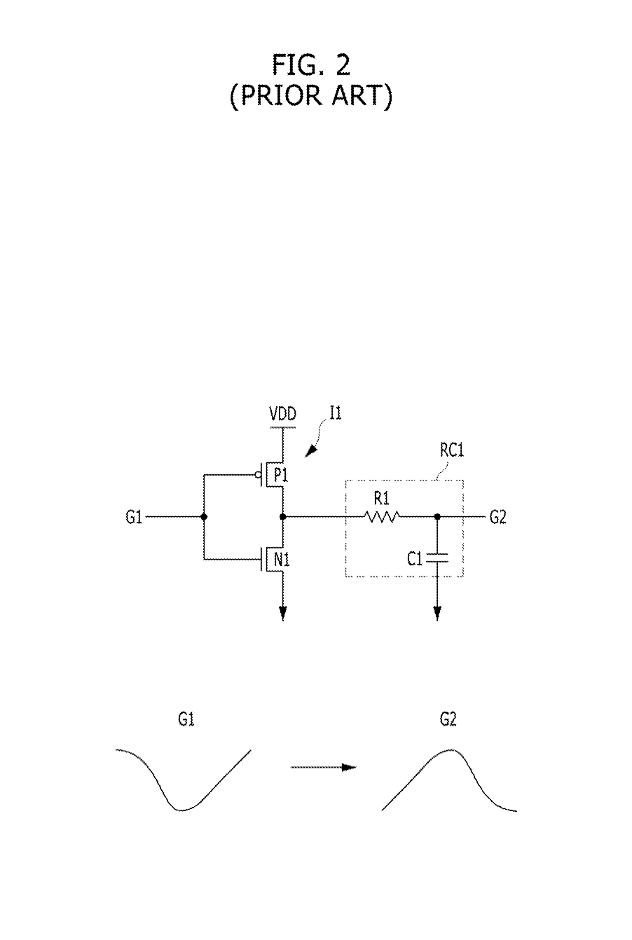

FIG. 2 is a schematic diagram illustrating an operation of the conventional oscillator shown in FIG. 1.

Referring to FIGS. 1 and 2, G1 represents a signal waveform inputted to the inverter I1 and G2 represents a signal waveform outputted from the RC delay unit RC1.

When the level of the signal inputted to the inverter I1 (G1) varies, the NMOS transistor N1 of the inverter I1 is incompletely turned on. This means that the NMOS transistor N1 has a greater resistance value than when the NMOS transistor N1 is completely turned on. The resistance value of the NMOS transistor N1 affects a delay value of the output signal (G2) of the RC delay unit RC1. As a result, the resistance value of the inverters I1 to I3 affects the period of the periodic signal OSC of the oscillator.

In sum, according to the prior art, the precision of the periodic signal OSC is heavily affected by PVT conditions and thus cannot be precisely adjusted with only the RC delay value.

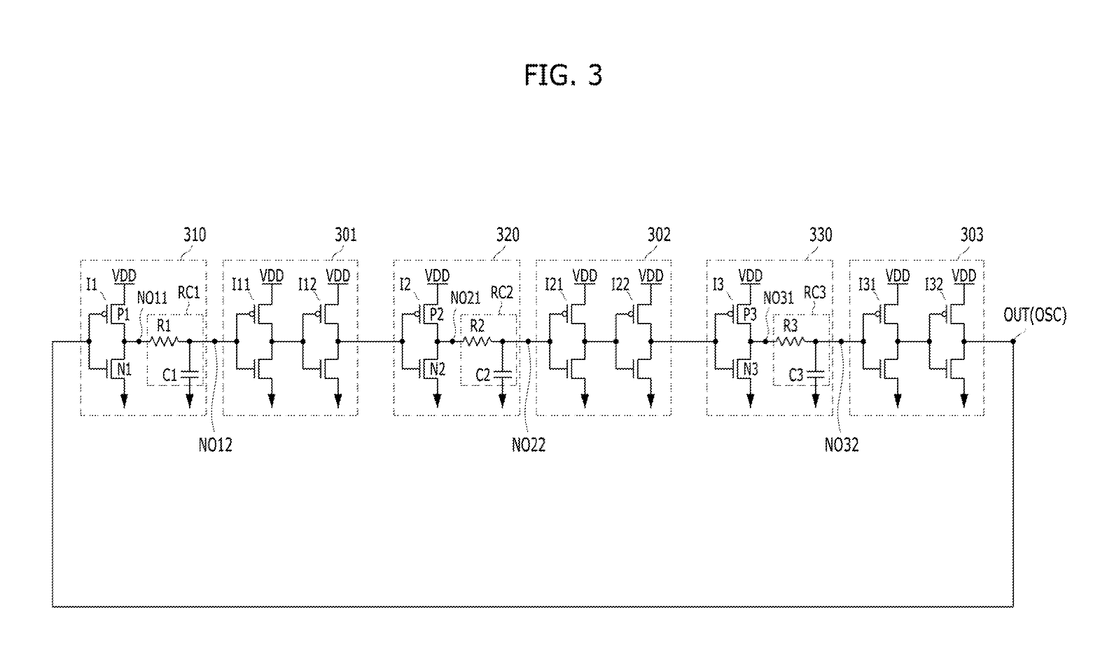

FIG. 3 is a circuit diagram illustrating an oscillator according to an exemplary embodiment of the present invention.

Referring to FIG. 3, the oscillator may include first to N delay units 310 to 330 and first to N buffers 301 to 303 (N is an odd number). FIG. 3 exemplarily illustrates three delay units 310 to 330 and three buffers 301 to 303, the number of which may vary according to circuit design. The oscillator may output a periodic signal through an output node OUT.

Each of the delay units 310 to 330 may delay and invert an input signal thereof. The delay units 310 to 330 may include inverters I1 to I3 and RC delay units RC1 to RC3, respectively.

The inverters I1 to I3 may respectively drive output nodes NO11 to NO31 thereof with a low level voltage when each voltage of input nodes thereof is higher than a reference voltage, and may respectively drive the output nodes NO11 to NO31 with a high level voltage when each voltage of the input nodes thereof is lower than the reference voltage. The inverters I1 to I3 may include NMOS transistors N1 to N3 and PMOS transistors P1 to P3, respectively.

Each of the RC delay units RC1 to RC3 may be electrically coupled between each of the inverters I1 to I3 and the buffers 301 to 303. For example, the RC delay units RC1 to RC3 may be electrically coupled between the output nodes NO11 to NO31 of the inverters I1 to I3 and input nodes NO12 to NO32 of the buffers 301 to 303, respectively. The RC delay units RC1 to RC3 may delay signals from the inverters I1 to I3 to output the delayed signals to the buffers 301 to 303, respectively. The RC delay units RC1 to RC3 may include resistive elements R1 to R3 and capacitive elements C1 to C3 which are electrically coupled between the output nodes NO11 to NO31 of the inverters I1 to I3 and the input nodes N01 to NO32 of the buffers 301 to 303.

The buffers 301 to 303 may output a high level voltage when a level of input signals thereof is higher than a reference voltage, and may output a low level voltage when the level of the input signals thereof is lower than the reference voltage. The high level voltage may be a power supply voltage VDD and the low level voltage may be a basal voltage VSS. The basal voltage VSS may be a ground voltage. The buffers 301 to 303 may recover the input signals thereof, which are distorted by the RC delay units RC1 to RC3, close in form to a step function. A K-th one of the buffers 301 to 303 (K is a natural number such that 1≦K≦N−1) may be electrically coupled between a K-th one and a (K+1)-th one of the delay units 310 to 330, and the last one of the buffers 301 to 303 may be electrically coupled between the last one and the first one of the delay units 310 to 330.

The buffers 301 to 303 may include pairs of inverters I11 to I32, each of which are serially and electrically coupled to each other, respectively. FIG. 3 exemplarily illustrates each of the buffers 301 to 303 including a pair of inverters. When the buffers 301 to 303 recover the input signals thereof near in form to the step function, the recovered signals similar to the step function may fully turn on NMOS transistors N1 to N3 or PMOS transistors P1 to P3 included in the inverters I1 to I3. The fully turned-on inverters I1 to I3 may significantly reduce the resistance values thereof, and thus the period of the periodic signal OSC is not as affected by the resistance value of the inverters I1 to I3 other than the RC delay value, and the period may be precisely adjusted. In sum, since the resistance value of the inverters I1 to I3 affecting the period of the periodic signal OSC other than the RC delay value of the RC delay units RC1 to RC3 are reduced, the period of the periodic signal OSC may be precisely adjusted by adjusting the RC delay value of the RC delay units RC1 to RC3 without consideration of the resistance value of the inverters I1 to I3.

For example, in order to determine the period of the periodic signal OSC according to the RC delay values of the RC delay units RC1 to RC3, the RC delay units RC1 to RC3 may have the resistance values of the resistive elements R1 to R3 greater than the resistance value of the turned-on inverters I1 to I3 and the turned-on buffers 301 to 303. In addition, the RC delay units RC1 to RC3 may have the RC delay values greater than delay values of the inverters I1 to I3 and the buffers 301 to 303.

The delay units 310 to 330 and the buffers 301 to 303 may form delay signal generation units, respectively. Each of the delay signal generation units including a single delay unit and a single buffer may invert an input signal thereof, may delay the inverted signal by the RC delay value of the RC delay unit, and may recover the delayed signal to a form that is near (or close to) the step function.

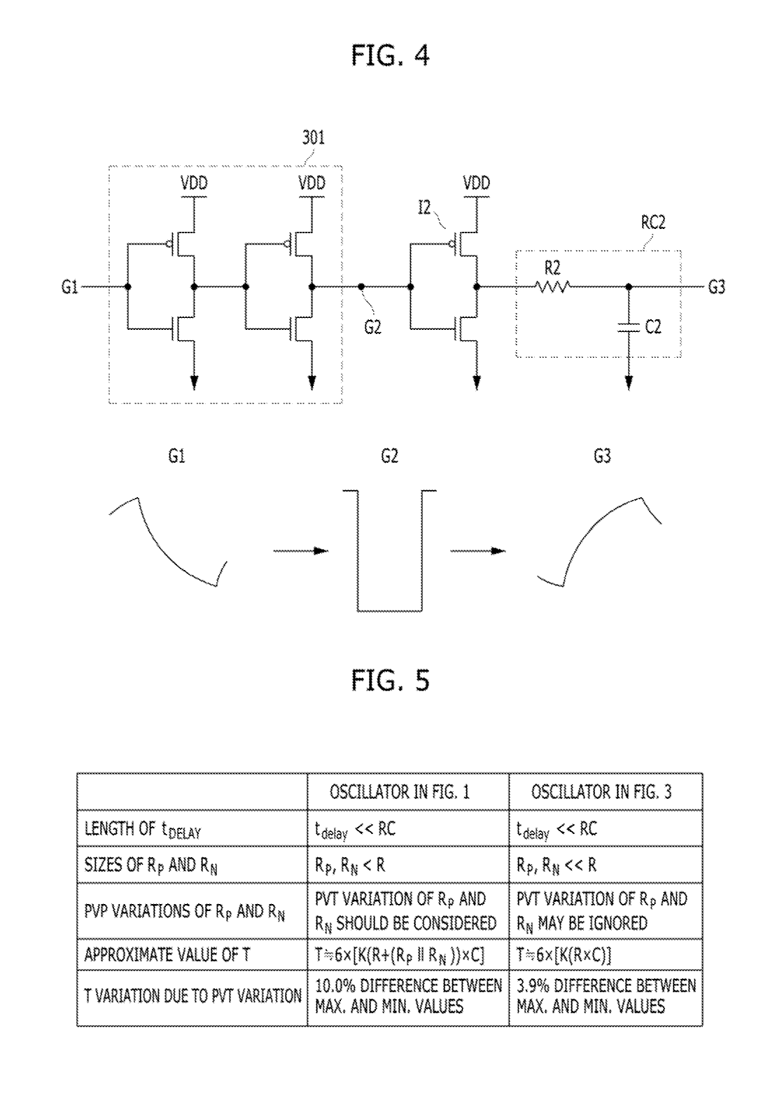

FIG. 4 is a schematic diagram illustrating an operation of the oscillator shown in FIG. 3.

Referring to FIGS. 3 and 4, G1 represents a signal waveform inputted to the buffer 301, G2 represents a signal waveform outputted from the buffer 301 to the inverter I2, and G3 represents a signal waveform outputted from the RC delay unit RC2 to a buffer 302.

Referring to FIG. 4, the signal (G1) distorted by the RC delay units RC1 to RC3 may be recovered by the buffers 301 to 303 in a form that is close to the step function (G2). Since the recovered signal (G2) toggles between a high level voltage and a low level voltage, transistors N2 and P2 in the inverter I2 may be completely turned on or turned off and the resistance values of the inverters I2 may be reduced. Thus, the period of the periodic signal OSC is less affected by the resistance value of the inverters I1 to I3 other than the RC delay value and the period may be precisely adjusted. In other words, influence of the inverters I1 to I3 on the period of the periodic signal OSC may be reduced, and thus, the period of the periodic signal OSC may be precisely adjusted by the delay values of the RC delay units RC1 to RC3 without consideration of the resistance value of the inverters I1 to I3.

As the number of inverters included in each of the buffers 301 to 303 increases, output signals from the buffers 301 to 303 may be closer to the step function while the inherent delay values of the inverters may increase. Accordingly, the shape of the output signal from the buffer may have trade-off relationship with inherent delay values of the buffer by the number of inverters included in the buffer.

FIG. 5 is a table illustrating operational parameters of oscillators shown in FIGS. 1 and 3.

A signal delay value T generated by a single delay unit, or both of a single delay unit and a single buffer of the oscillator is represented by the following equation 1.

T=6×[k(R+(R_{P}∥R_{N}))×C+t_{delay}] [Equation 1]

Here, t_{delay} represents a delay value generated by the inverter and the buffer, R_{P} represents a turn-on resistance value of the PMOS transistor of the inverter and the buffer, R_{N} is a turn-on resistance value of the NMOS transistor of the inverter and the buffer, and k is a constant value of In (2/√5−1). The operation “R_{P}∥R_{N}” represents an equivalent resistance value of R_{P} and R_{N} electrically coupled in parallel.

Referring to FIG. 5, t_{delay} of the oscillator shown in FIGS. 1 and 2 may be approximated to be relatively small compared to the RC delay value of a RC delay unit. In the oscillator of FIG. 1, the turn-on resistance values R_{P} and R_{N} of the transistors may be assumed to be small compared to the resistance values of the resistors R1 to R3 in the RC delay units RC1 to RC3. In the oscillator of FIG. 3, the turn-on resistance values R_{P} and R_{N}, of the transistors may be assumed to be relatively small compared to the resistance values of the resistors R1 to R3 in the RC delay units RC1 to RC3. In the oscillator of FIG. 1, the PVT variations of the turn-on resistance values R_{P} and R_{N} should be considered. However, the oscillator of FIG. 3, since the turn-on resistance values R_{P} and R_{N} are relatively small, PVT variation influence on the turn on resistance values R_{P} and R_{N} of the signal delay value T may be ignored.

Finally, T is approximated to the following equations 2 and 3 for the oscillators of FIGS. 1 and 3 respectively.

T≈6×[k(R+(R_{P}∥R_{N}))×C] [Equation 2]

T≈6×[k(R×C)] [Equation 3]

In the oscillator of FIG. 1, a difference between maximum and minimum values in the period of the periodic signal OSC generated due to the PVT variation is 10.8 In the oscillator of FIG. 3, a difference between maximum and minimum values in the period of the periodic signal OSC generated due to the PVT variation may be 3.9%, which is significantly small.

That is, in the oscillator of FIG. 3, the period is not less affected by PVT variations compared to the period in the oscillator of FIG. 1. Thus, in accordance with an exemplary embodiment of the present invention, the period of the periodic signal OSC may be precisely adjusted by the RC delay value of the RC delay unit without consideration of the PVT variations.

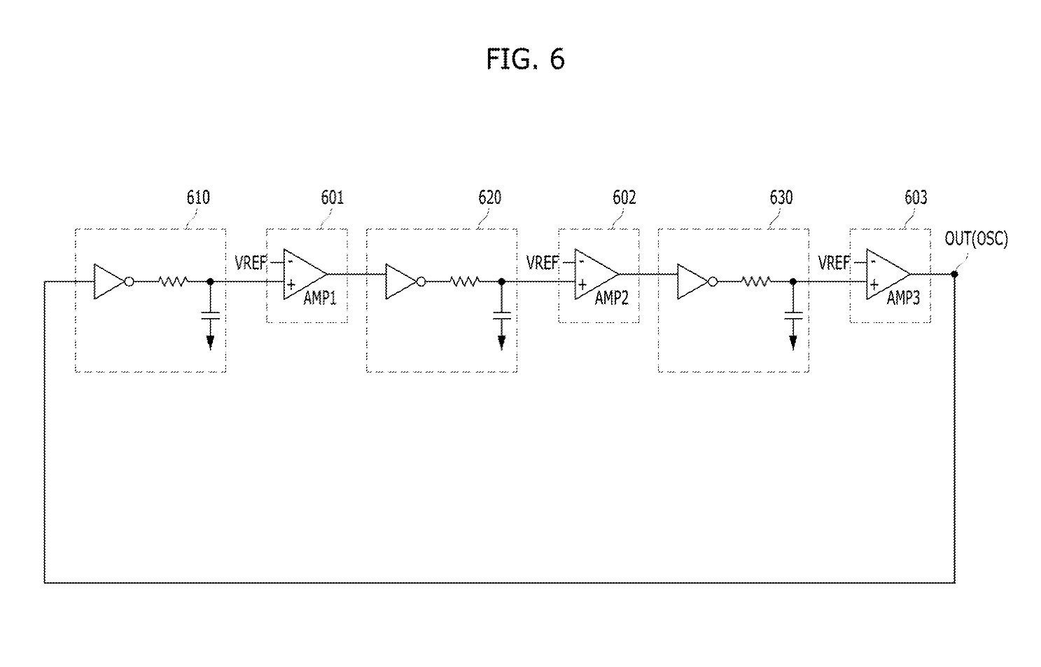

FIG. 6 is a circuit diagram illustrating an oscillator according to an exemplary embodiment of the present invention.

Referring to FIG. 6, the oscillator may include first to N-th delay units (N is an odd number) 610 to 630, first to N-th buffers 601 to 603. FIG. 6 exemplarily illustrates three delay units 610 to 630 and three buffers 601 to 603, the number of which may vary according to circuit design. The oscillator may output a periodic signal OSC through an output node OUT.

The buffers 601 to 603 may include amplifiers (or comparators) AMP1 to AMP3, respectively. The amplifiers AMP1 to AMP3 may output a high level voltage when each level of input signals thereof is higher than a reference voltage VREF, and may output a low level voltage when the level of the input signals is lower than the reference voltage VREF. The operation of the buffers 601 to 603 may be the same as the buffers 301 to 303 described above with reference to FIG. 3. The operation of the oscillator shown in FIG. 6 may be the same as the oscillator described with reference to FIGS. 3 to 5.

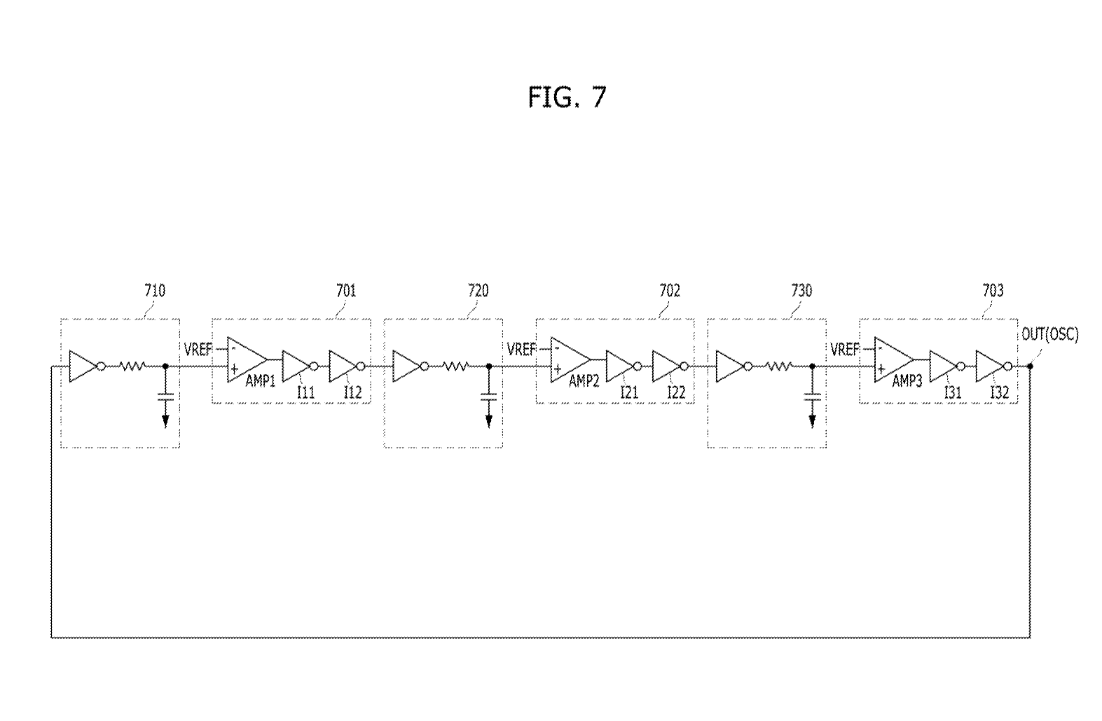

FIG. 7 is a circuit diagram illustrating an oscillator according to an exemplary embodiment of the present invention.

Referring to FIG. 7, the oscillator may include first to N-th delay units (N is an odd number) 710 to 730, first to N-th buffers 701 to 703. FIG. 7 exemplarily illustrates three delay units 710 to 730 and three buffers 701 to 703, the number of which may vary according to circuit design. The oscillator may output a periodic signal OSC through an output node OUT.

The buffers 701 to 703 may include amplifiers (or comparators) AMP1 to AMP3 and serially and electrically coupled odd number of inverter pairs I11 to I32. The buffers 701 to 703 may output a high level voltage when each level of input signals thereof is higher than a reference voltage VREF, and may output a low level voltage when the level of the input signals is lower voltage than the reference voltage VREF. The coupling order of the amplifiers AMP1 to AMP3 and the inverter pair I11 to I32 included in each of the buffers 701 to 703 may vary according to circuit design. The operation of the buffers 701 to 703 may be the same as the buffers 301 to 303 described above with reference to FIG. 3. The operation of the oscillator shown in FIG. 7 may be the same as the oscillator described with reference to FIGS. 3 to 5.

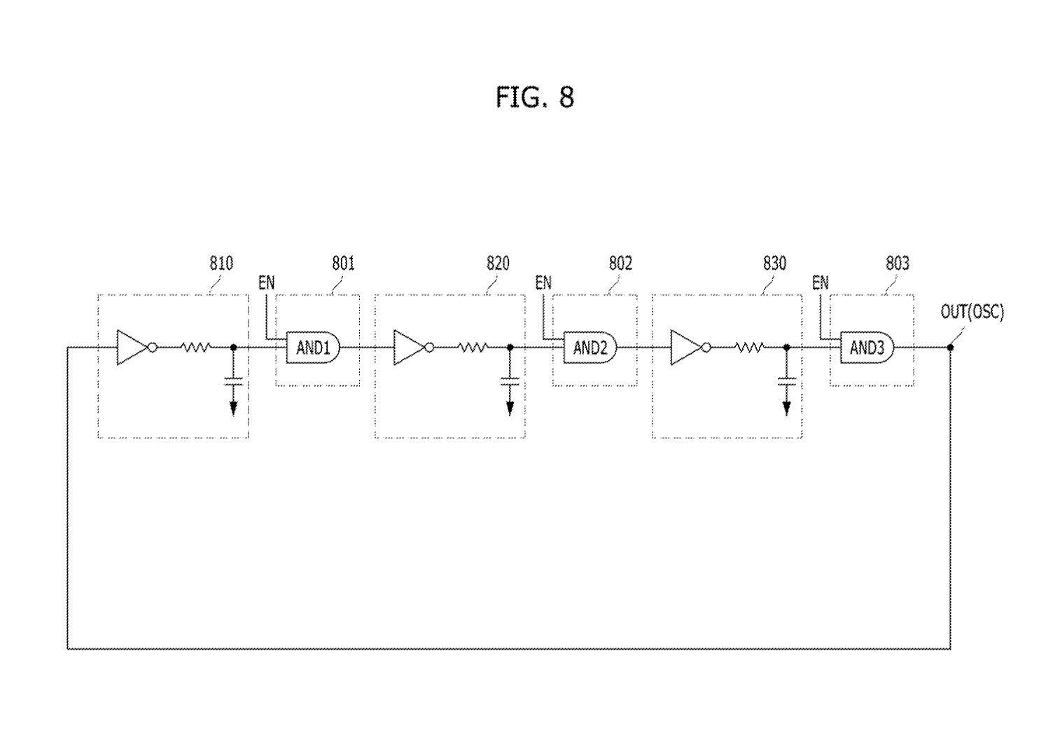

FIG. 8 is a circuit diagram illustrating an oscillator according an exemplary embodiment of the present invention.

Referring to FIG. 8, the oscillator may include first to N-th delay units (N is an odd number) 810 to 830, and first to N-th buffers 801 to 803. FIG. 8 exemplarily illustrates three delay units 810 to 830 and three buffers 801 to 803, the number of which may vary according to circuit design. The oscillator may output a periodic signal OSC through an output node OUT.

The buffers 801 to 803 may include AND gates AND1 to AND3. When an enable signal EN is activated, the buffers 801 to 803 may output a high level voltage when each level of input signals thereof is higher than a reference voltage and may output a low level voltage when the level of the input signals is lower than the reference voltage. The operation of the buffers 801 to 803 may be the same as the buffers 301 to 303 described above with reference to FIG. 3. The operation of the oscillator shown in FIG. 8 may be the same as the oscillator described with reference to FIGS. 3 to 5.

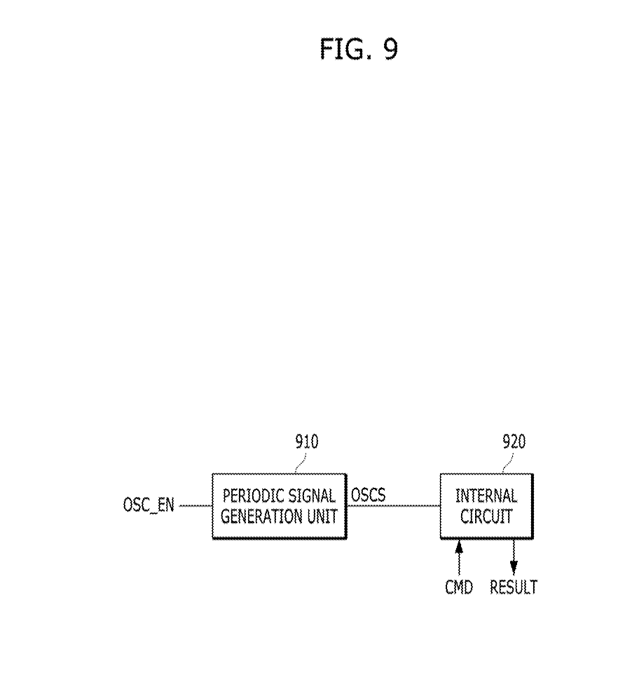

FIG. 9 is a block diagram illustrating a semiconductor device according to an exemplary embodiment of the present invention.

Referring to FIG. 9, the semiconductor device may include a periodic signal generation unit 910 and an internal circuit 920.

The periodic signal generation unit 910 may generate a periodic signal OSCS when an activation signal OSC_EN is activated. The periodic signal generation unit 910 may include one of the oscillators described with reference to FIGS. 3 to 8. The periodic signal OSCS may be a periodic signal OSC generated by the oscillator or a signal obtained by dividing the periodic signal OSC generated by the oscillator.

The internal circuit 920 may operate in synchronization with the periodic signal OSCS. For example, the internal circuit 920 may perform a self-refresh operation for a memory device with a period corresponding to the periodic signal OSCS. For another example, the internal circuit 920 may generate a pumping voltage in response to the periodic signal OSCS. In addition, the internal circuit 920 may generate an operation result signal RESULT in response to a command CMD. The internal circuit 920 may be synchronized with the periodic signal OSCS.

A period of the periodic signal OSCS may be precisely adjusted by the RC delay value of the RC delay unit included in the periodic signal generation unit 910 without consideration of the PVT variation of the periodic signal generation unit 910, and thus the internal circuit 920 may operate with a precise frequency.

Although various embodiments have been described for illustrative purposes, it will be apparent to those skilled in the art that various changes and modifications may be made without departing from the spirit and scope of the invention as defined in the following claims.

1. An oscillator comprising first to N-th delay signal generation units (N being an odd number), each of which delays and inverts an input signal thereof,
wherein each of the first to N-th delay signal generation units comprises:
an inverter suitable for driving a first node with a low level voltage when a voltage of an input node thereof is higher than a first reference voltage, and driving the first node with a high level voltage when the voltage of the input node thereof is lower than the first reference voltage;
a RC delay unit electrically coupled between the first node and a second node, and suitable for delaying a signal of the first node and outputting the delayed signal of the first node to the second node; and
a buffer suitable for outputting a high level signal when a voltage of the second node is higher than a second reference voltage, and outputting a low level signal when the voltage of the second node is lower than the second reference voltage, wherein the buffer is coupled to the RC delay unit in series.

2. The oscillator of claim 1,
wherein the first to N-th delay signal generation units are electrically coupled in series, and
wherein output of the N-th delay signal generation unit is fed back to the first delay signal generation unit.

3. The oscillator of claim 1, wherein the RC delay unit comprises:
a resistive element electrically coupled between the first node and the second node; and
a capacitive element electrically coupled to the second node.

4. The oscillator of claim 3, wherein a resistance value of the resistive element is greater than a turn-on resistance value of the inverter and the buffer.

5. The oscillator of claim 1, wherein a delay value of the RC delay unit is greater than delay values of the inverter and the buffer.

6. The oscillator of claim 1, wherein the buffer includes an even number of inverters which are electrically coupled in series.

7. The oscillator of claim 1, wherein the buffer includes an amplifier.

8. The oscillator of claim 1, wherein the buffer includes an amplifier and an even number of inverters which are electrically coupled in series.

9. An oscillator comprising:
first to N-th delay units (N being an odd number), each of which delays and inverts an input signal thereof; and
first to N-th buffers, each of which outputs a high level signal when a level of an input signal thereof is higher than a first reference voltage and outputs a low level signal when the level of the input signal thereof is lower than the first reference voltage,
wherein the first to N-th delay units and the first to N-th buffers are alternately and electrically coupled in series,
wherein the N-th buffer is electrically coupled between the N-th delay unit and the first delay unit, and
wherein each of the first to N-th delay units comprises:
an inverter suitable for driving a first node with a low level voltage when a voltage of an input node thereof is higher than a second reference voltage and driving the first node with a high level voltage when the voltage of the input node thereof is lower than the second reference voltage; and
a RC delay unit electrically coupled between the first node and a second node, and suitable for delaying a signal of the first node and outputting the delayed signal of the first node to the second node, wherein the N-th buffer is coupled to a corresponding RC delay unit in series.

10. (canceled)

11. The oscillator of claim 9, wherein the RC delay unit comprises:
a resistive element electrically coupled between the first node and the second node; and
a capacitive element electrically coupled to the second node.

12. The oscillator of claim 9, wherein the buffer includes an even number of inverters which are serially electrically coupled.

13. The oscillator of claim 9, wherein the buffer includes an amplifier.

14. The oscillator of claim 9, wherein the buffer includes an amplifier and an even number of inverters which are serially electrically coupled.

15. A semiconductor device comprising:
a periodic signal generation unit suitable for generating a periodic signal; and
an internal circuit suitable for operating in synchronization with the periodic signal,
wherein the periodic signal generation unit comprises:
first to N-th delay units (N is an odd number), each of which delays and inverts an input signal thereof; and
first to N-th buffers, each of which outputs a high level signal when a level of an input signal thereof is higher than a first reference voltage and outputs a low level signal when the level of the input signal thereof is lower than the first reference voltage,
wherein the first to N-th delay units and the first to N-th buffers are alternately and electrically coupled in series,
wherein the N-th buffer is electrically coupled between the N-th delay unit and the first delay unit, and
wherein each of the first to N-th delay units comprises:
an inverter suitable for driving a first node with a low level voltage when a voltage of an input node thereof is higher than a second reference voltage and driving the first node with a high level voltage when the voltage of the input node thereof is lower than the second reference voltage; and
a RC delay unit electrically coupled between the first node and a second node, and suitable for delaying a signal of the first node and outputting the delayed signal of the first node to the second node, wherein the N-th buffer is coupled to a corresponding RC delay unit in series.

16. (canceled)

17. The semiconductor device of claim 15, wherein the RC delay unit comprises:
a resistive element electrically coupled between the first node and the second node; and
a capacitive element electrically coupled to the second node.

18. The semiconductor device of claim 15, wherein the buffer includes an even number of inverters which are serially electrically coupled.

19. The semiconductor device of claim 15, wherein the buffer includes an amplifier.

20. The semiconductor device of claim 15, wherein the buffer includes an amplifier and an even number of inverters which are serially electrically coupled.
